(19) United States
(12) Patent Application Publication
(10) Pub. No.: US 2024/0413165 A1
(43) Pub. Date: Dec. 12, 2024

(54) THIN FILM TRANSISTOR, ELECTRONIC DEVICE, MANUFACTURING METHOD OF ELECTRONIC DEVICE, AND DISPLAY DEVICE

(71) Applicant: WUHAN CHINA STAR OPTOELECTRONICS SEMICONDUCTOR DISPLAY TECHNOLOGY CO., LTD., WUHAN, HUBEI (CN)

(72) Inventors: Hui Zheng, Wuhan, Hubei (CN); Haiyan Shen, Wuhan, Hubei (CN); Wenxu Xianyu, Wuhan, Hubei (CN); Can Huang, Wuhan, Hubei (CN); Chunpeng Zhang, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/617,295

(22) PCT Filed: Nov. 24, 2021
(86) PCT No.: PCT/CN2021/132632

§ 371 Date: Aug. 20, 2024

(30) Foreign Application Priority Data
Nov. 15, 2021 (CN) 202111348254.9

(51) Int. Cl. H01L 27/12; H01L 29/66; H01L 29/786

(52) U.S. Cl. CPC H01L 27/1225; H01L 29/7869; H01L 29/66742

(57) ABSTRACT

The present disclosure provides a thin film transistor, an electronic device, a manufacturing method of electronic device, and display device. The thin film transistor includes a driving circuit layer including a first metal layer, a first insulating layer, a second metal layer, a second insulating layer, and a third metal layer stacked together; wherein one of the first, the second, and the third metal layer is configured to be a gate, and the another two are configured to be a source and a drain; a gate insulating layer disposed on a sidewall of the driving circuit layer, and a semiconductor layer disposed on a surface of the gate insulating layer.

### FIELD OF INVENTION

The present disclosure relates to the field of thin film transistor technologies and particularly to a thin film transistor, an electronic device, a manufacturing method of the electronic device, and a display device.

### BACKGROUND OF INVENTION

A channel layer (a semiconductor layer or an active layer) of the traditional thin film transistor device is placed in parallel, and a source/drain on both sides of the channel layer is electrically conducted to the channel layer through via lines, and the via lines occupy a large area, which is not conducive to reducing a volume of the thin film transistor, and thus not conducive to improving pixels per inch (PPI) of an image.

### INVENTION SUMMARY

### Technical Question

A technical problem to be solved in the present disclosure is how to increase PPI of an image.

### Solutions to the Question

### Solutions to the Technique

In order to solve the above technical problem, technical solutions provided by the present disclosure are as follows:

The present disclosure provides a thin film transistor, including:
a driving circuit layer comprising a first metal layer, a first insulating layer, a second metal layer, a second insulating layer, and a third metal layer stacked together; wherein one of the first metal layer, the second metal layer, and the first metal layer is configured to be a gate of the thin film transistor, and the other two of the first metal layer, the second metal layer, and the third metal layer are configured to be a source of the thin film transistor and a drain of the thin film transistor;
a gate insulating layer disposed on a sidewall of the driving circuit layer; and
a semiconductor layer disposed on a surface of the gate insulating layer away from the driving circuit layer; wherein the semiconductor layer includes a drain doped region, a source doped region, and a channel region; the drain doped region and the source doped regions are respectively electrically connected to two metal layers forming the drain of the thin film transistor and the source of the thin film transistor of the first metal layer, the second metal layer, and the third metal layer; and the channel region is opposite to a metal layer of the first metal layer, the second metal layer, and the third metal layer configured to be the gate of the thin film transistor.

In an optional embodiment of the present disclosure, the second metal layer is the gate of the thin film transistor, the first metal layer is the source of the thin film transistor, and the third metal layer is the drain of the thin film transistor; the second metal layer is located between the first metal layer and the third metal layer, the channel region is located between the drain doped region and the source doped region, the drain doped region is horizontally disposed on the third metal layer relative to the driving circuit layer and electrically connected to the third metal layer, the source doped region is horizontally disposed on the first metal layer relative to the driving circuit layer and electrically connected to the first metal layer, and the channel region is formed on a surface of the gate insulating layer away from the driving circuit layer.

In an optional embodiment of the present disclosure, the source doped region and the first insulating layer are located on a same surface of the first metal layer.

In an optional embodiment of the present disclosure, the metal layer of the first metal layer, the second metal layer, and the third metal layer configured to be the gate of the thin film transistor is located above or below the metal layers configured to be the source of the thin film transistor and the drain of the thin film transistor of the first metal layer, the second metal layer, and the third metal layer;
via holes are defined in the gate insulating layer, and the via holes respectively correspond to the two metal layers of the first metal layer, the second metal layer, and the third metal layer configured to be the source of the thin film transistor and the drain of the thin film transistor;
the channel region is opposite to the metal layer of the first metal layer, the second metal layer, and the third metal layer configured to be the gate of the thin film transistor; and
the drain doped region and the source doped region are electrically connected to the two metals configured to be the source of the thin film transistor and the train of the thin film transistor of the first metal layer, the second metal layer, and the third metal layer respectively penetrate through the via holes.

In an optional embodiment of the present disclosure, the thin film transistor further includes a substrate, and one of the first metal layer, the second metal layer, and the third metal layer is formed on the substrate.

In an optional embodiment of the present disclosure, the thin film transistor further includes a flattening layer, the flattening layer is formed on the semiconductor layer and sidewalls of a metal layer formed on the substrate of the first metal layer, the second metal layer, and the third metal layer.

The present disclosure also provides an electronic device, including a substrate and a plurality of thin film transistors formed on the substrate; wherein the electronic device further includes:
a driving circuit layer comprising a first metal layer, a first insulating layer, a second metal layer, a second insulating layer, and a third metal layer stacked together; wherein one of the first metal layer, the second metal layer, and the first metal layer is configured to be a gate of the thin film transistor, and the other two of the first metal layer, the second metal layer, and the third metal layer are configured to be a source and a drain of the thin film transistor;
a gate insulating layer disposed on a sidewall of the driving circuit layer; and
a semiconductor layer disposed on a surface of the gate insulating layer away from the driving circuit layer; wherein the semiconductor layer includes a drain doped region, a source doped region, and a channel region; the drain doped region and the source doped regions are respectively electrically connected to two metal layers forming the drain of the thin film transistor and the source of the thin film transistor of the first metal layer, the second metal layer, and the third metal layer; and the channel region is opposite to a metal layer of the first metal layer, the second metal layer, and the third metal layer configured to be the gate of the thin film transistor; and
channel grooves and division grooves communicating with each other; wherein the channel grooves and the division grooves are formed on the substrate and penetrate through the first metal layer, the first insulating layer, the second metal layer; the gate insulating layers of at least two of the thin film transistors are formed on a sidewall of one of the channel grooves; and a part of the semiconductor layers of at least two of the thin film transistors is formed on the gate insulating layer and the other part is formed on the sidewalls of the division grooves.

In an optional embodiment of the present disclosure, between two adjacent thin film transistors, one of the channel grooves corresponds to multiple division grooves, each of the division grooves comprises an extension area and an intersection area, the intersection areas of multiple division grooves converge together; and the intersection areas of multiple division grooves overlap the channel groove.

In an optional embodiment of the present disclosure, each of the thin film transistors is located between two adjacent division grooves.

In an optional embodiment of the present disclosure, different thin film transistors are formed on a same flattening layer, and the flattening layer covers the semiconductor layer and is filled in the division grooves.

In an optional embodiment of the present disclosure, a material of the channel region of the semiconductor layer is indium gallium zinc oxide or heterojunction structure composed of indium gallium zinc oxide and indium zinc oxide.

The present disclosure also provides a manufacturing method of an electronic device, including:
step S1: providing an array substrate, wherein the array substrate comprises a substrate, a first metal layer, a first insulating layer, a second metal layer, a second insulating layer, and a third metal layer stacked together; one of the first metal layer, the second metal layer, and the first metal layer is configured to be a gate of the thin film transistor, and the other two of the first metal layer, the second metal layer, and the third metal layer are configured to be a source and a drain of the thin film transistor;
step S2: defining at least one channel groove on the array substrate; wherein the channel groove penetrates through film layers of the array substrate excepting for the substrate and the metal layer formed on the substrate of the first metal layer, the second metal layer, and the third metal layer;
step S3: forming a gate insulating layer on a sidewall of the channel groove;
step S4: forming a semiconductor layer formed on the gate insulating layer, on the metal layers of the array substrate away from the substrate, and on sidewalls of the channel groove not covered by the gate insulating layer; and
step S5: defining a plurality of division grooves in the substrate from a bottom of the channel groove to the array substrate, to divide the array substrate into a plurality of thin film transistors.

In an optional embodiment of the present disclosure, the manufacturing method further includes:

step S6: forming a flattening layer on the semiconductor layer; wherein a part of the flattening layer is filled in the division grooves.

In an optional embodiment of the present disclosure, the step S3 includes:
forming an initial gate insulating layer on an inner wall of the channel groove and the metal layer of the array substrate away from the substrate; and
patterning the initial gate insulating layer to obtain the gate insulating layer.

In an optional embodiment of the present disclosure, the step S4 includes:
forming an initial semiconductor layer on the gate insulating layer, the substrate exposed from the channel groove, and exposed portions of the first metal layer, the second metal layer, and the third metal layer; and wherein the initial semiconductor layer comprises a channel region corresponding to the gate insulating layer;
forming a doped protective layer on the channel region; and
doping ions in a region of the initial semiconductor layer not covered by the doped protective layer to form a drain doped region and a source doped region, and removing the doped protective layer; wherein the drain doped region and the source doped regions are respectively electrically connected to two metal layers forming the drain of the thin film transistor and the source of the thin film transistor of the first metal layer, the second metal layer, and the third metal layer; and the channel region is opposite to a metal layer of the first metal layer, the second metal layer, and the third metal layer configured to be the gate of the thin film transistor.

The present disclosure also provides an display device, including:
light-emitting functional layer; and
an electronic device, wherein the light-emitting function layer is electrically connected to the electronic device, and the electronic device comprises a substrate and a plurality of thin film transistors formed on the substrate; and wherein the electronic device further includes:
a driving circuit layer comprising a first metal layer, a first insulating layer, a second metal layer, a second insulating layer, and a third metal layer stacked together; wherein one of the first metal layer, the second metal layer, and the first metal layer is configured to be a gate of the thin film transistor, and the other two of the first metal layer, the second metal layer, and the third metal layer are configured to be a source and a drain of the thin film transistor;
a gate insulating layer disposed on a sidewall of the driving circuit layer; and
a semiconductor layer disposed on a surface of the gate insulating layer away from the driving circuit layer; wherein the semiconductor layer comprises a drain doped region, a source doped region, and a channel region; the drain doped region and the source doped regions are respectively electrically connected to two metal layers forming the drain of the thin film transistor and the source of the thin film transistor of the first metal layer, the second metal layer, and the third metal layer; and the channel region is opposite to a metal layer of the first metal layer, the second metal layer, and the third metal layer configured to be the gate of the thin film transistor; and
channel grooves and division grooves communicating with each other; wherein the channel grooves and the division grooves are formed on the substrate and penetrate through the first metal layer, the first insulating layer, the second metal layer; the gate insulating layers of at least two of the thin film transistors are formed on a sidewall of one of the channel grooves; and a part of the semiconductor layers of at least two of the thin film transistors is formed on the gate insulating layer and the other part is formed on the sidewalls of the division grooves.

In an optional embodiment of the present disclosure, between two adjacent thin film transistors, one of the channel grooves corresponds to multiple division grooves, each of the division grooves comprises an extension area and an intersection area, the intersection areas of multiple division grooves converge together; and the intersection areas of multiple division grooves overlap the channel groove.

In an optional embodiment of the present disclosure, the second metal layer is the gate of the thin film transistor, the first metal layer is the source of the thin film transistor, and the third metal layer is the drain of the thin film transistor; the second metal layer is located between the first metal layer and the third metal layer, the channel region is located between the drain doped region and the source doped region, the drain doped region is horizontally disposed on the third metal layer relative to the driving circuit layer and electrically connected to the third metal layer, the source doped region is horizontally disposed on the first metal layer relative to the driving circuit layer and electrically connected to the first metal layer, and the channel region is formed on a surface of the gate insulating layer away from the driving circuit layer.

In an optional embodiment of the present disclosure, a material of the channel region of the semiconductor layer is indium gallium zinc oxide or heterojunction structure composed of indium gallium zinc oxide and indium zinc oxide.

### BENEFICIAL EFFECTS OF THE INVENTION

### Beneficial Effects

In the thin film transistor, the electronic device and the display device provided by the present disclosure, the source layer, the drain layer and the gate layer in the driving circuit layer are stacked together, the gate insulating layer and the semiconductor layer (channel layer or active layer) are disposed on the sidewall of the driving circuit layer and the semiconductor layer is electrically connected to the source layer and the drain layer, respectively, so that the source layer, the drain layer and the semiconductor layer can be electrically connected without through via lines, thereby reducing an occupied area of the thin film transistor and increasing a number of devices per unit area, thereby improving sampling rate and pixels of image.

In addition, the present disclosure defines a channel groove in the array substrate and is configured to be a gate insulating layer and a semiconductor layer on inner walls of the channel groove, and then forms division grooves communicating with the channel groove, thereby manufacturing multiple thin film transistors at the same time, thus, production efficiency of the thin film transistors can be improved.

Due to an energy band structure of indium gallium zinc oxide is different from an energy band structure of indium zinc oxide, the two materials touching causes the two materials can be bend at an interface between the two materials, so that, electrons are confined to a lower energy interface, so scattering effect of the electrons by is reduced, and mobility of the electrons is increased, so employing heterojunction structure composed of indium gallium zinc oxide and indium zinc oxide as the material of the channel region of the semiconductor layer can increase the mobility of the indium gallium zinc oxide and achieve the effect of improving image pixels.

### BRIEFLY DESCRIPTION FOR DRAWINGS

### Description of Drawings

In order to explain embodiments or technical solutions in the prior art more clearly, the following will briefly introduce drawings involved in a following description of the embodiments or the prior art. Obviously, the drawings in the following description are merely inventions. Those of ordinary skill in the art can obtain other drawings based on these drawings without creative work.

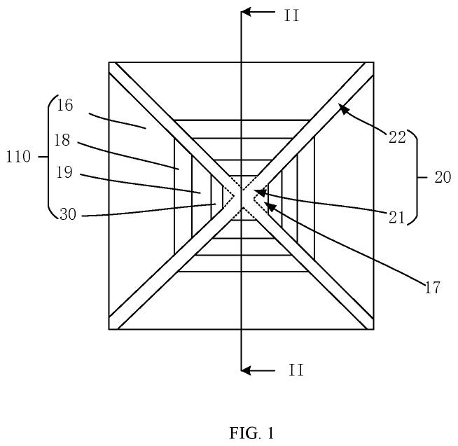

FIG. 1 is a schematic top view of an electronic device (not including a passivation layer) provided by a preferred embodiment of the present disclosure.

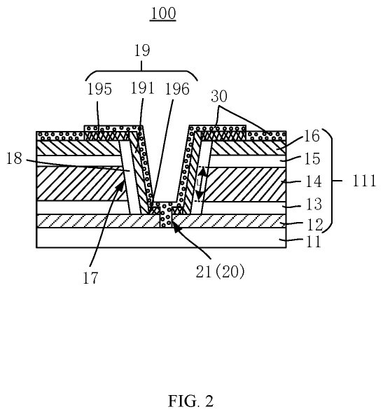

FIG. 2 is a schematic cross-sectional view along II-II shown in FIG. 1.

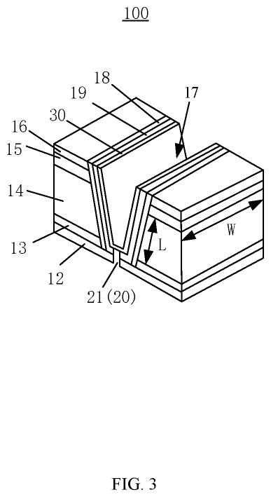

FIG. 3 is a three-dimensional side view of the electronic device shown in FIG. 1 that removes two thin film transistors disposed opposite to each other.

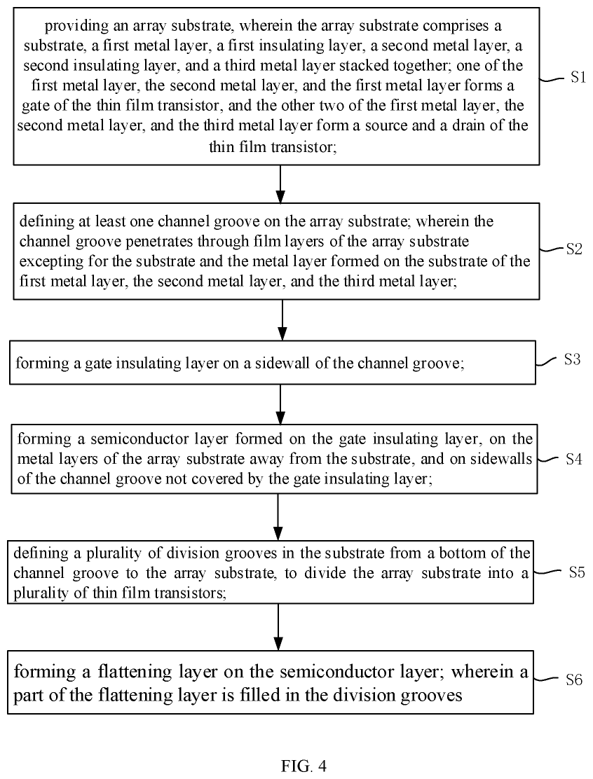

FIG. 4 is a flow chart of a manufacturing method of the electronic device provided in the present disclosure.

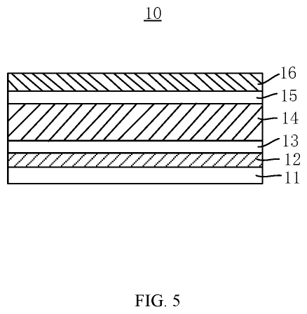

FIG. 5 is a schematic cross-sectional view of an array substrate provided by a preferred embodiment of the present disclosure.

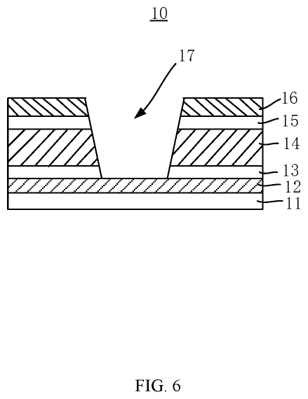

FIG. 6 is a schematic cross-sectional view showing that at least one channel groove is formed in the array substrate shown in FIG. 5.

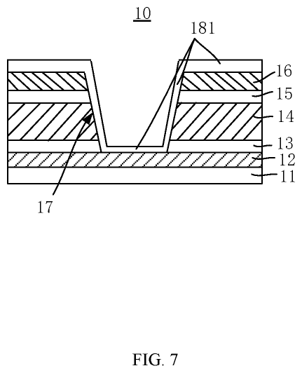

FIG. 7 is a schematic cross-sectional view showing that an initial gate insulating layer is formed on an inner wall of the channel groove and a surface of the array substrate shown in FIG. 6.

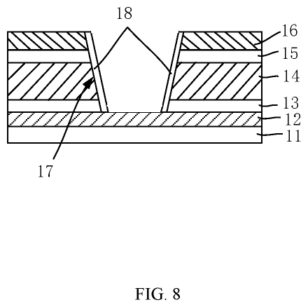

FIG. 8 is a schematic cross-sectional view showing that the initial gate insulating layer shown in FIG. 7 is patterned to form a gate insulating layer.

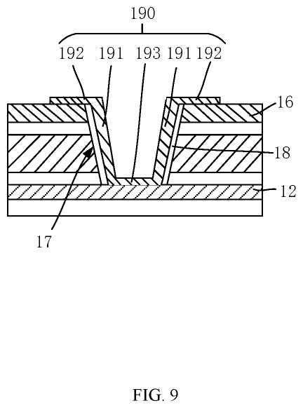

FIG. 9 is a schematic cross-sectional view showing that an initial semiconductor layer is formed on a surface of the gate insulating layer and a part of a surface of the array substrate shown in FIG. 8.

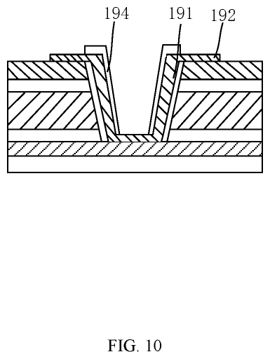

FIG. 10 is a schematic cross-sectional view showing that a doped protective layer is formed on the initial semiconductor layer shown in FIG. 9.

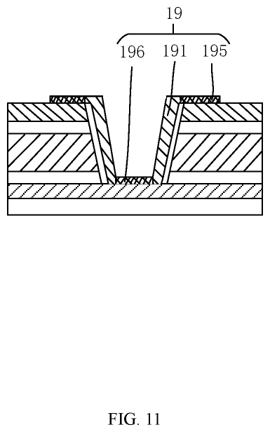

FIG. 11 is a schematic cross-sectional view showing that heavy metal ions are doped in an initial semiconductor layer not covered by the doped protective layer shown in FIG. 10 to form a semiconductor layer.

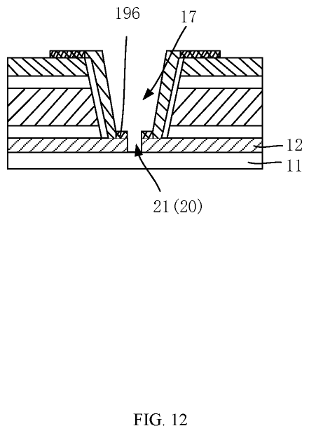

FIG. 12 is a schematic cross-sectional view showing that division grooves are formed between a bottom of the semiconductor layer shown in FIG. 11 and a substrate of the array substrate.

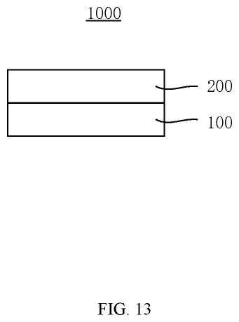

FIG. 13 is a schematic view of a display device provided in the present disclosure.

### EMBODIMENTS FOR INVENTION

### Detailed Description of Embodiments

The technical solutions in the embodiments of the present disclosure will be clearly and completely described in conjunction with the drawings in the embodiments of the present disclosure. Obviously, the described embodiments are only a part of the embodiments of the present disclosure, rather than all the embodiments. Based on the embodiments in the present disclosure, all other embodiments obtained by those skilled in the art without creative work shall fall within a protection scope of the present disclosure.

In the description of the present disclosure, it should be understood that, an orientation or positional relationship indicated by terms “upper”, “lower”, etc. are based on an orientation or positional relationship shown in the drawings, and is only for convenience of describing the disclosure and simplifying the description. It does not indicate or imply that a pointed device or an element must have a specific orientation, or be configured and operated in a specific orientation, and therefore it cannot be understood as a limitation of the present disclosure. In addition, terms “first” and “second” are only used for descriptive purposes, and cannot be understood as indicating or implying relative importance or implicitly indicating a number of indicated technical features. Therefore, the features defined with “first” and “second” may explicitly or implicitly include one or more of the features. In the description of the present disclosure, “a plurality of” means two or more, unless otherwise specifically defined.

The present disclosure may repeat reference numerals and/or reference letters in different implementations, and this repetition is for a purpose of simplification and clarity, and does not indicate a relationship between various embodiments and/or settings discussed.

The present disclosure addresses a technical problem that an existing thin film transistors occupy a large area, which is not conducive to reducing volume of the thin film transistors, and thus is not conducive to improving PPI of an image. The present disclosure makes a source layer, a drain layer, and a gate layer in a driving circuit layer be stacked together, and makes a gate insulating layer and a semiconductor layer (a channel layer or an active layer) be disposed on a sidewall of the driving circuit layer, and makes the semiconductor layer to be electrically connected to the source layer and the drain layer, respectively, so that the source layer, the drain layer, and the semiconductor layer can be electrically connected without going through via lines, thereby reducing an occupied area of the thin film transistor and increasing a number of devices per unit area, thereby improving a sampling rate and pixels of an image. In addition, the present disclosure defines a channel groove in the array substrate and is configured to be a gate insulating layer and a semiconductor layer on inner walls of the channel groove, and then forms division grooves communicating with the channel groove, thereby manufacturing multiple thin film transistors at the same time, thus, production efficiency of the thin film transistors can be improved.

The thin film transistor and the electronic device of the present application will be described in detail below in conjunction with specific embodiments.

Please refer to FIGS. 1-3, a preferred embodiment of the present disclosure provides an electronic device 100. The electronic device 100 includes a substrate 11 and a plurality of thin film transistors 110 formed on the substrate 11.

Wherein, each of the thin film transistors 110 includes a driving circuit layer 111, a gate insulating layer 18, and a semiconductor layer 19. The gate insulating layer 18 is disposed on a sidewall of the driving circuit layer 111, and the semiconductor layer 19 is disposed on a surface of the gate insulating layer 18 away from the driving circuit layer 111.

Wherein, the driving circuit layer 111 includes a first metal layer 12, a first insulating layer 13, a second metal layer 14, a second insulating layer 15, and a third metal layer 16. The first metal layer 12, the first insulating layer 13, the second metal layer 14, the second insulating layer 15, and the third metal layer 16 are vertically stacked together. The second metal layer 14 is located between the first metal layer 12 and the third metal layer 16. One of the first metal layer 12, the second metal layer 14, and the third metal layer 16 is configured to be a gate of the thin film transistor 110, and another two of the first metal layer 12, the second metal layer 14, and the third metal layer 16 are configured to be a source of the thin film transistor 110 and a drain of the thin film transistor 110.

Wherein, the semiconductor layer 19 includes a drain doped region 195, a source doped region 196, and a channel region 191. An doping amount of metal ions in the drain doped region 195 is less than an doping amount of metal ions in the source doped region 196. Therefore, the drain doped region 195 corresponds to a drain layer, and the source doped region 196 corresponds to a source layer. The channel region 191 is formed on a surface of the gate insulating layer 18 away from the driving circuit layer 111. The drain doped region 195 and the source doped region 196 are respectively electrically connected to two metal layers of the first metal layer 12, the second metal layer 14, and the third metal layer 16 configured to be the source and the drain of the thin film transistor 110. The channel region 191 is opposite to a metal layer of the first metal layer 12, the second metal layer 14, and the third metal layer 16 configured to be the gate of the thin film transistor 110.

In this embodiment, a material of the channel region 191 is indium gallium zinc oxide (IGZO). In another optional embodiment of the present disclosure, the material of the channel region 191 may also be heterojunction structure composed of indium gallium zinc oxide and indium zinc oxide. Due to an energy band structure of indium gallium zinc oxide is different from an energy band structure of indium zinc oxide, touching of the two materials causes the two materials to bend at an interface between the two materials, so that electrons are confined to a lower energy interface, so a scattering effect of the electrons by is reduced, and mobility of the electrons is increased. Therefore, employing a heterojunction structure composed of indium gallium zinc oxide and indium zinc oxide as the material of the channel region of the semiconductor layer can increase the mobility of the indium gallium zinc oxide and achieve an effect of improving image pixels.

Specifically, in this embodiment, the first metal layer 12 is the source of the thin film transistor 110, the second metal layer 14 is the gate of the thin film transistor 110, and the third metal layer 16 is the drain of the thin film transistor 110. The first insulating layer 13 is stacked on the first metal layer 12, the second metal layer 14 is stacked on the first insulating layer 13, the second insulating layer 15 is stacked on the second metal layer 14, and the third metal layer 16 is stacked on the second insulating layer 15. The drain doped region 195 is horizontally formed on the third metal layer 16 relative to the driving circuit layer 111. The drain doped region 195 is electrically connected to the third metal layer 16. The source doped region 196 is horizontally disposed on the first metal layer 12 relative to the driving circuit layer 111. The source doped region 196 is electrically connected to the first metal layer 12. The channel region 191 is formed on a surface of the gate insulating layer 18 away from the driving circuit layer 111.

Specifically, in another embodiment of the present disclosure, the first metal layer 12 may also be the drain of the thin film transistor 110, the second metal layer 14 is the gate of the thin film transistor 110, and the third metal layer 16 is the source of the thin film transistor 110. The drain doped region 195 is horizontally disposed on the first metal layer 12 relative to the driving circuit layer 111 and is electrically connected to the first metal layer 12, and the source doped region 196 is horizontally disposed on the third metal layer 16 relative to the driving circuit layer 111 and electrically connected to the third metal layer 16, and the channel region 191 is formed on the surface of the gate insulating layer 18 away from the driving circuit layer 111.

Specifically, in another embodiment of the present disclosure, one of the first metal layer 12 and the third metal layer 16 is the gate of the thin film transistor 110, that is, an outermost metal layer of the gate of the driving circuit layer 111 is the gate of the thin film transistor 110. At this time, one of the drain doped region 195 and the source doped region 196 is electrically connected to an outermost metal layer of the driving circuit layer 111 serving as the drain or source of the thin film transistor 110, and another one of the drain doped region 195 and the source doped region 196 is electrically connected to an inner metal layer of the driving circuit layer 111 serving as the drain or source of the thin film transistor 110. The channel region 191 is opposite to the first metal layer 12 or the third metal layer 16 serving as the gate of the thin film transistor 110. Specifically, the drain doped region 195 or the source doped region 196 can be electrically connected to the inner metal layer of the driving circuit layer 111 serving as the drain or source of the thin film transistor 110 by a via hole (not shown) horizontally passing through the gate insulating layer 18.

Please refer to FIG. 2, in this embodiment, the source doped region 196 and the first insulating layer 13 are located on a same surface of the first metal layer 12.

Please refer to FIG. 2 again, the thin film transistor 110 further includes a substrate 11. One of the first metal layer 12, the second metal layer 14, and the third metal layer 16 is formed on the substrate 11. In this embodiment, the first metal layer 12 is formed on the substrate 11.

Please refer to FIG. 2 again, the thin film transistor 110 further includes a flattening layer 30 formed on the semiconductor layer 19 and on sidewalls of a metal layer formed on the substrate 11 of the first metal layer 12, the second metal layer 14, and the third metal layer 16. In this embodiment, the flattening layer 30 covers the semiconductor layer 19 and a part of the third metal layer 16. The flattening layer 30 is filled in division grooves 20 (see below) to cover a surface of the first metal layer 12 perpendicular to an end surface of the substrate 11. In this embodiment, the flattening layer 30 located in the division grooves 20 is in contact with the substrate 11.

Please refer to FIGS. 1 and 2 again, the electronic device 100 further includes channel grooves 17 and division grooves 20 communicating with each other. The channel grooves 17 and the division grooves 20 are formed on the substrate 11 and penetrate the first metal layer 12, the first insulating layer 13, the second metal layer 14, the second insulating layer 15, and the third metal layer 16. The gate insulating layers 18 of two thin film transistors 110 are formed on sidewalls of the channel grooves 17. The semiconductor layers 19 of the two thin film transistors 110 are partially formed on the gate insulating layer 18 and another portion is formed on sidewalls of the division grooves 20.

Wherein, between two adjacent thin film transistors 110, one of the channel grooves 17 corresponds to multiple division grooves 20, each of the division grooves 20 includes an extension area 22 and an intersection area 21, the intersection areas 21 of multiple division grooves 20 converge together; and the intersection areas 21 of multiple division grooves 20 overlap the channel groove 17.

Wherein, each of the thin film transistors 110 is located between two adjacent division grooves 20.

Wherein, different thin film transistors 110 share a same flattening layer 30, and the flattening layer 30 covers the semiconductor layer 19 and is filled in the division grooves 20.

In this embodiment, the electronic device 100 includes four thin film transistors 110 and four division grooves 20, and the four division grooves 20 are distributed like a cross, each thin film transistor 110 is located between two adjacent division grooves 20.

Referring to FIG. 3, an end surface of the second metal layer 14 serving as the gate of each thin film transistor 110 facing the gate insulating layer 18 has a length L from 0.1 um to 5 um, and a width W from 0.1 um to 8 um. Wherein, the length of the end surface of the gate insulating layer 18 means a vertical distance between a surface of the gate insulating layer 18 touching the first insulating layer 13 and a surface of the gate insulating layer 18 touching the second insulating layer 15 on the end surface of the second metal layer 14 serving as the gate facing the gate insulating layer 18. Too large W/L can easily cause a short channel effect and excessive leakage current, and too small W/L can easily cause high power consumption of the device.

Please refer to FIGS. 4-12, the present disclosure also provides a manufacturing method of the electronic device 100, including:
Step S1, please refer to FIGS. 4-5, providing an array substrate 10, wherein the array substrate 10 includes a substrate 11, a first metal layer 12, a first insulating layer 13, a second metal layer 14, a second insulating layer 15, and a third metal layer 16 stacked together. One of the first metal layer 12, the second metal layer 14, and the first metal layer 16 is configured to be a gate of the thin film transistor, and another two of the first metal layer 12, the second metal layer 14, and the third metal layer 16 are configured to be a source of the thin film transistor and a drain of the thin film transistor 110.

Wherein, the second metal layer 14 is located between the first metal layer 12 and the third metal layer 16. The first metal layer 12, the first insulating layer 13, the second metal layer 14, the second insulating layer 15, and the third metal layer 16 form a driving circuit layer 111 of the thin film transistor.

Specifically, in this embodiment, the first metal layer 12 is the source of the thin film transistor 110, the second metal layer 14 is the gate of the thin film transistor 110, and the third metal layer 16 is the drain of the thin film transistor 110. The first insulating layer 13 is stacked on the first metal layer 12, the second metal layer 14 is stacked on the first insulating layer 13, the second insulating layer 15 is stacked on the second metal layer 14, and the third metal layer 16 is stacked on the second insulating layer 15.

Specifically, in another embodiment of the present disclosure, the first metal layer 12 may also be the drain of the thin film transistor, the second metal layer 14 is the gate of the thin film transistor, and the third metal layer 16 is the source of the thin film transistor.

Specifically, in another embodiment of the present disclosure, one of the first metal layer 12 and the third metal layer 16 is the gate of the thin film transistor, that is, an outermost metal layer of the driving circuit layer 111 is the gate of the thin film transistor.

Please refer to FIG. 5 again, the array substrate 10 further includes a substrate 11, and one of the first metal layer 12, the second metal layer 14, and the third metal layer 16 is formed on the substrate 11. In this embodiment, the first metal layer 12 is formed on the substrate 11.

Step S2, please refer to FIG. 5, defining at least one channel groove 17 on the array substrate 10; wherein the channel groove 17 penetrates through film layers of the array substrate 10 excepting for the substrate 11 and the metal layer of the first metal layer 12, the second metal layer 14, and the third metal layer 16 formed on the substrate 11.

In this embodiment, the channel groove 17 penetrates the first insulating layer 13, the second metal layer 14, the second insulating layer 15, and the third metal layer 16.

In this embodiment, the channel groove 17 has an inverted trapezoid shape. In other embodiments, a shape of the channel groove 17 is not limited to an inverted trapezoid, and can be determined according to actual conditions.

In other embodiments, the channel groove 17 penetrates the first metal layer 12, the first insulating layer 13, the second metal layer 14, and the second insulating layer 15.

Step S3, please refer to FIGS. 7 and 8, forming a gate insulating layer 18 on a sidewall of the channel groove 17.

Specifically, the gate insulating layer 18 is formed on the sidewall of the driving circuit layer 111.

In an optional embodiment of the present disclosure, the step S3 includes: firstly, referring to FIG. 7, forming an initial gate insulating layer 181 on an inner wall of the channel groove 17 and the third metal layer 16 or the first metal layer 12. An inner wall of the channel groove 17 includes an inner side wall (not numbered in the figure) facing the driving circuit layer 111 and a bottom wall (not numbered in the figure) connected to the inner side wall. In this embodiment, the bottom wall refers to the first metal layer 12 exposed from the channel groove 17. Secondly, referring to FIG. 8, patterning the initial gate insulating layer 181 to obtain the gate insulating layer 18.

In an optional embodiment of the present application, the initial gate insulating layer 181 may be patterned through processes such as exposure, development, and etching.

Step S4, please refer to FIGS. 9 to 11, forming a semiconductor layer 19 formed on the gate insulating layer 18, on metal layers of the array substrate 10 away from the substrate 11, and on sidewalls of the channel groove 17 not covered by the gate insulating layer 18.

In this embodiment, the semiconductor layer 19 is formed on the gate insulating layer 18, a part of the third metal layer 16, and the first metal layer 12 exposed from the channel groove 17.

In an optional embodiment of the present application, the step S4 includes:

Firstly, referring to FIG. 9, forming an initial semiconductor layer 190 on the gate insulating layer 18, a part of the third metal layer 16 or the first metal layer 12, and the first metal layer 12 or the third metal layer 16 exposed from the channel groove 17. The initial semiconductor layer 190 includes a channel region 191 corresponding to the gate insulating layer 18, and a first to-be-doped region 192 and a second to-be-doped region 193 respectively connected to the channel region 191.

Secondly, referring to FIG. 10, forming a doped protection layer 194 on the channel region 191; and

Thirdly, referring to FIG. 11, doping ions in a region (the first to-be-doped region 192 and the second to-be-doped region 193) of the initial semiconductor layer 190 not covered by the doped protective layer to form a drain doped region 195 and a source doped region 196, and removing the doped protective layer 194.

Specifically, in this embodiment, the drain doped region 195 is formed on the third metal layer 16, and the source doped region 196 is formed on the first metal layer 12.

Wherein, the doped protection layer 194 may be selected from but not limited to PR (reverse photoresist), and the PR is served as a mask for doping.

Wherein, metal ions doped in the drain doped region 195 and the source doped region 196 may be P-type metal ions or N-type metal ions.
Step S5, referring to FIG. 12, defining a plurality of division grooves 20 in the substrate 11 from a bottom of the channel groove 17 to the substrate 11 to divide the array substrate 10 into a plurality of thin film transistors 110.

Wherein, a plurality of the thin film transistors 110 and the substrate 11 form the electronic device 100.

Wherein, the channel grooves 17 and division grooves 20 are communicated with each other. Two adjacent thin film transistors 110 are divided away by the division grooves 20. Each of the division grooves 20 includes an extension area 22 and an intersection area 21, the intersection areas 21 of multiple division grooves 20 converge together; and the intersection areas 21 of multiple division grooves 20 overlap the channel groove 17.

In this embodiment, the electronic device 100 includes four thin film transistors 110 and four division grooves 20, and four division grooves 20 are distributed like a cross, each thin film transistor 110 is located between two adjacent division grooves 20.

In other embodiments, a number of the thin film transistors 110 included in each of the electronic devices 100 is not limited to four, and can also be two, three, five, six, eight, etc., and a specific number can be determined according to the actual situation. The division grooves 20 are not limited to a cross-like distribution, and can be determined according to actual conditions.
Step S6, referring to FIG. 2, forming a flattening layer 130 on the semiconductor layer 19.

In this embodiment, the flattening layer 130 is formed on the third metal layer 16.

Wherein, the flattening layer 130 is filled in the division grooves 20.

Referring to FIG. 13, the present disclosure also provides a display device 1000 including: a light-emitting function layer 200; and the electronic device 100 as described above, and the light-emitting function layer 200 is electrically connected to the electronic device 100.

In the thin film transistor, the electronic device, and the display device provided by the present disclosure, the source layer and the drain layer in the driving circuit layer are stacked together, the semiconductor layer (the channel layer or the active layer) are disposed on the sidewall of the driving circuit layer and the semiconductor layer is electrically connected to the source layer and the drain layer, respectively, so that the source layer, the drain layer, and the semiconductor layer can be electrically connected without going through via lines, thereby reducing an occupied area of the thin film transistor and increasing a number of devices per unit area, thereby improving a sampling rate and pixels of an image.

In addition, the present disclosure defines a channel groove in the array substrate and is configured to be a gate insulating layer and a semiconductor layer on inner walls of the channel groove, and then forms division grooves communicating with the channel groove, thereby manufacturing multiple thin film transistors at the same time, thus, production efficiency of the thin film transistors can be improved.

Due to an energy band structure of indium gallium zinc oxide is different from an energy band structure of indium zinc oxide, touching of the two materials causes the two materials to bend at an interface between the two materials, so that electrons are confined to a lower energy interface, so a scattering effect of the electrons by is reduced, and mobility of the electrons is increased, so employing heterojunction structure composed of indium gallium zinc oxide and indium zinc oxide as the material of the channel region of the semiconductor layer can increase the mobility of the indium gallium zinc oxide and achieve the effect of improving image pixels.

The description of the above embodiments is only used to help understand the technical solutions and core ideas of the disclosure, those of ordinary skill in the art should understand that: they can still modify the technical solutions recorded in the foregoing embodiments, or equivalently replace some of the technical features, and these modifications or replacements do not cause the essence of the corresponding technical solutions to deviate from the scope of the technical solutions of the embodiments of the present disclosure.

What is claimed is:

1. A thin film transistor, comprising:
a driving circuit layer comprising a first metal layer, a first insulating layer, a second metal layer, a second insulating layer, and a third metal layer stacked together; wherein one of the first metal layer, the second metal layer, and the third metal layer is configured to be a gate of the thin film transistor, and another two of the first metal layer, the second metal layer, and the third metal layer are configured to be a source of the thin film transistor and a drain of the thin film transistor;
a gate insulating layer disposed on a sidewall of the driving circuit layer; and
a semiconductor layer disposed on a surface of the gate insulating layer away from the driving circuit layer; wherein the semiconductor layer comprises a drain doped region, a source doped region, and a channel region; the drain doped region and the source doped regions are respectively electrically connected to two metal layers of the first metal layer, the second metal layer, and the third metal layer forming the drain of the thin film transistor and the source of the thin film transistor; the channel region is disposed opposite to the one of the first metal layer, the second metal layer, and the third metal layer configured to be the gate of the thin film transistor.

2. The thin film transistor of claim 1, wherein the second metal layer is the gate of the thin film transistor, the first metal layer is the source of the thin film transistor, and the third metal layer is the drain of the thin film transistor; and wherein the second metal layer is located between the first metal layer and the third metal layer, the channel region is located between the drain doped region and the source doped region; the drain doped region is disposed on the third metal layer, horizontally, relative to the driving circuit layer and electrically connected to the third metal layer, the source doped region is disposed on the first metal layer, horizontally, relative to the driving circuit layer and electrically connected to the first metal layer; the channel region is formed on a surface of the gate insulating layer away from the driving circuit layer.

3. The thin film transistor of claim 2, wherein the source doped region and the first insulating layer are located on a same surface of the first metal layer.

4. The thin film transistor of claim 1, wherein the metal layer of the first metal layer, the second metal layer, and the third metal layer configured to be the gate of the thin film transistor is located above or below metal layers of the first metal layer, the second metal layer, and the third metal layer configured to be the source of the thin film transistor and the drain of the thin film transistor;
via holes are defined in the gate insulating layer, and the via holes respectively correspond to two metal layers of the first metal layer, the second metal layer, and the third metal layer configured to be the source of the thin film transistor and the drain of the thin film transistor;
the channel region is opposite to the metal layer of the first metal layer, the second metal layer, and the third metal layer configured to be the gate of the thin film transistor; and
the drain doped region and the source doped region are electrically connected to the two metal layers configured to be the source of the thin film transistor and the drain of the thin film transistor of the first metal layer, the second metal layer, and the third metal layer respectively through the via holes.

5. The thin film transistor of claim 1, wherein the thin film transistor further comprises a substrate, and one of the first metal layer, the second metal layer, and the third metal layer is formed on the substrate.

6. The thin film transistor of claim 5, wherein the thin film transistor further comprises a flattening layer, the flattening layer is formed on the semiconductor layer and on sidewalls of a metal layer of the first metal layer, the second metal layer, and the third metal layer disposed on the substrate.

7. The thin film transistor of claim 1, wherein a material of the channel region of the semiconductor layer is indium gallium zinc oxide or heterojunction structure composed of indium gallium zinc oxide and indium zinc oxide.

8. An electronic device, comprising a substrate and a plurality of thin film transistors formed on the substrate; wherein the electronic device further comprises:
a driving circuit layer comprising a first metal layer, a first insulating layer, a second metal layer, a second insulating layer, and a third metal layer stacked together on the substrate; wherein one of the first metal layer, the second metal layer, and the first metal layer is configured to be a gate of the thin film transistor, and another two of the first metal layer, the second metal layer, and the third metal layer are configured to be a source and a drain of the thin film transistor;
a gate insulating layer disposed on a sidewall of the driving circuit layer; and
a semiconductor layer disposed on a surface of the gate insulating layer away from the driving circuit layer; wherein the semiconductor layer comprises a drain doped region, a source doped region, and a channel region; the drain doped region and the source doped regions are respectively electrically connected to two metal layers forming the drain of the thin film transistor and the source of the thin film transistor of the first metal layer, the second metal layer, and the third metal layer; the channel region is opposite to a metal layer of the first metal layer, the second metal layer, and the third metal layer configured to be the gate of the thin film transistor; and
channel grooves and division grooves communicating with each other; wherein the channel grooves and the division grooves are formed on the substrate and penetrate through the first metal layer, the first insulating layer, the second metal layer, the second insulating layer, and the third metal layer; the gate insulating layers of two of the thin film transistors are formed on a sidewall of one of the channel grooves; a part of the semiconductor layers of at least two of the thin film transistors is formed on the gate insulating layer and another part is formed on the sidewalls of the division grooves.

9. The electronic device of claim 8, wherein between two adjacent thin film transistors, one of the channel grooves corresponds to multiple division grooves, each of the division grooves comprises an extension area and an intersection area; the intersection areas of multiple division grooves converge together, and the intersection areas of multiple division grooves overlap the channel grooves.

10. The electronic device of claim 9, wherein each of the thin film transistors is located between two adjacent division grooves.

11. The electronic device of claim 8, wherein different thin film transistors are formed on a same flattening layer, and the flattening layer covers the semiconductor layer and is filled in the division grooves.

12. The electronic device of claim 8, wherein a material of the channel region of the semiconductor layer is indium gallium zinc oxide or heterojunction structure composed of indium gallium zinc oxide and indium zinc oxide.

13. A manufacturing method of an electronic device, comprising:
step S1: providing an array substrate, wherein the array substrate comprises a substrate, a first metal layer, a first insulating layer, a second metal layer, a second insulating layer, and a third metal layer stacked together; one of the first metal layer, the second metal layer, and the first metal layer is configured to be a gate of the thin film transistor, and another two of the first metal layer, the second metal layer, and the third metal layer are configured to be a source of the thin film transistor and a drain of the thin film transistor;
step S2: defining at least one channel groove on the array substrate; wherein the channel groove penetrates through film layers of the array substrate excepting for the substrate and the metal layer of the first metal layer, the second metal layer, and the third metal layer formed on the substrate;
step S3: forming a gate insulating layer on a sidewall of the channel groove;
step S4: forming a semiconductor layer formed on the gate insulating layer, on metal layers of the array substrate away from the substrate, and on sidewalls of the channel groove not covered by the gate insulating layer; and
step S5: defining a plurality of division grooves in the substrate from a bottom of the channel groove to the substrate to divide the array substrate into a plurality of thin film transistors.

14. The manufacturing method of claim 13, wherein the manufacturing method further comprises:
step S6: forming a flattening layer on the semiconductor layer; wherein the flattening layer is filled in the division grooves.

15. The manufacturing method of claim 13, wherein the step S3 comprises:
forming an initial gate insulating layer on an inner wall of the channel groove and metal layer of the array substrate away from the substrate; and
patterning the initial gate insulating layer to obtain the gate insulating layer.

16. The manufacturing method of claim 14, wherein the step S4 comprises:
forming an initial semiconductor layer on the gate insulating layer, on a substrate exposed from the channel groove, and on exposed portions of the first metal layer, the second metal layer, and the third metal layer; wherein the initial semiconductor layer comprises a channel region corresponding to the gate insulating layer;
forming a doped protective layer on the channel region; and
doping ions in a region of an initial semiconductor layer not covered by the doped protective layer to form a drain doped region and a source doped region, and removing the doped protective layer; wherein the drain doped region and the source doped region are respectively electrically connected to two metal layers forming the drain of the thin film transistor and the source of the thin film transistor of the first metal layer, the second metal layer, and the third metal layer; the channel region is opposite to a metal layer of the first metal layer, the second metal layer, and the third metal layer configured to be the gate of the thin film transistor.

17. A display device, wherein, comprises:
a light-emitting functional layer; and
an electronic device, wherein the light-emitting functional layer is electrically connected to the electronic device, and the electronic device comprises a substrate and a plurality of thin film transistors formed on the substrate; and wherein the electronic device comprises:
a driving circuit layer comprising a first metal layer, a first insulating layer, a second metal layer, a second insulating layer, and a third metal layer stacked together on the substrate; wherein one of the first metal layer, the second metal layer, and the first metal layer is configured to be a gate of the thin film transistor, and the other two of the first metal layer, the second metal layer, and the third metal layer are configured to be a source and a drain of the thin film transistor;
a gate insulating layer disposed on a sidewall of the driving circuit layer; and
a semiconductor layer disposed on a surface of the gate insulating layer away from the driving circuit layer; wherein the semiconductor layer comprises a drain doped region, a source doped region, and a channel region; the drain doped region and the source doped regions are respectively electrically connected to two metal layers forming the drain of the thin film transistor and the source of the thin film transistor of the first metal layer, the second metal layer, and the third metal layer; and the channel region is opposite to a metal layer of the first metal layer, the second metal layer, and the third metal layer configured to be the gate of the thin film transistor; and
channel grooves and division grooves communicating with each other; wherein the channel grooves and the division grooves are formed on the substrate and penetrate through the first metal layer, the first insulating layer, the second metal layer, the second insulating layer, and the third metal layer; the gate insulating layers of at least two of the thin film transistors are formed on a sidewall of one of the channel grooves; and a part of the semiconductor layers of at least two of the thin film transistors is formed on the gate insulating layer and the another part is formed on the sidewalls of the division grooves.

18. The display device of claim 17, wherein between two adjacent thin film transistors, one of the channel grooves corresponds to multiple division grooves, each of the division grooves comprises an extension area and an intersection area, the intersection areas of multiple division grooves converge together; and the intersection areas of multiple division grooves overlap the channel groove.

19. The display device of claim 17, wherein the second metal layer is the gate of the thin film transistor, the first metal layer is the source of the thin film transistor, and the third metal layer is the drain of the thin film transistor; the second metal layer is located between the first metal layer and the third metal layer, the channel region is located between the drain doped region and the source doped region; the drain doped region is horizontally disposed on the third metal layer relative to the driving circuit layer and electrically connected to the third metal layer, the source doped region is horizontally disposed on the first metal layer relative to the driving circuit layer and electrically connected to the first metal layer, and the channel region is formed on a surface of the gate insulating layer away from the driving circuit layer.

20. The display device of claim 17, wherein a material of the channel region of the semiconductor layer is indium gallium zinc oxide or heterojunction structure composed of indium gallium zinc oxide and indium zinc oxide.
